(19) United States
(12) Patent Application Publication
(10) Pub. No.: US 2022/0181509 A1
(43) Pub. Date: Jun. 9, 2022

(54) PHOTOVOLTAIC CELL AND PHOTOVOLTAIC MODULE

(71) Applicant: Meyer Burger (Germany) GmbH, Hohenstein-Ernstthal (DE)

(72) Inventors: Harald HAHN, Dresden (DE); Sven WENDT, Dresden (DE)

(21) Appl. No.: 17/680,431

(22) Filed: Feb. 25, 2022

Related U.S. Application Data
(63) Continuation-in-part of application No. 15/144,890, filed on May 3, 2016.

(30) Foreign Application Priority Data
May 4, 2015 (DE) 20 2015 102 238.7

(51) Int. Cl. H01L 31/056; H01L 31/068; H01L 31/049

(52) U.S. Cl. CPC H01L 31/056; H01L 31/049; H01L 31/0684

(57) ABSTRACT

In various embodiments, a photovoltaic module is provided. The photovoltaic module may include a plurality of electrically interconnected photovoltaic cells. The photovoltaic cell may include a substrate with a front-side and a rear-side, and a metallization on the rear-side of the substrate. At least some of the plurality of electrically interconnected photovoltaic cells are at least partially bifacial photovoltaic cells. The photovoltaic module may further include an encapsulation of the plurality of photovoltaic cells. A first transparent cover may be arranged over the encapsulation, and a second transparent cover may be arranged over the encapsulation. A diffuse rear-side reflector may be arranged over the encapsulation where the diffuse rear-side reflector is disposed at a distance from the second transparent cover in the range from approximately 0.5 cm to 20 cm from the rear-side surface of the second transparent cover.

### CROSS-REFERENCE TO RELATED APPLICATION

This application is a Continuation-in-Part and claims priority to U.S. application Ser. No. 15/144,890 filed on May 3, 2016; which claims priority to German Utility Model Application Serial No. 20 2015 102 238.7, which was filed May 4, 2015; both of which are incorporated herein by reference in its entirety and for all purposes.

### TECHNICAL FIELD

Various embodiments relate generally to photovoltaic cells and photovoltaic modules manufactured with these.

### BACKGROUND

A photovoltaic module usually has a plurality of electrically interconnected photovoltaic cells. The photovoltaic cells are adjacently disposed at a distance from each other within a photovoltaic module, so that there is a gap between every two contiguous photovoltaic cells, which is generally filled with an encapsulation material.

The light penetrating through the cell gaps, which therefore does not reach the light incident side of the photovoltaic cells, significantly contributes in reducing the output of a photovoltaic module.

For this reason, different developments were implemented to make this light available. So it is currently possible to increase the power generation in a photovoltaic module by light captured in the cell gaps. In today's photovoltaic module, approximately 30% of the light reaching the cell gaps is resupplied to the photovoltaic cells by means of total reflection on the upper glass cover of the photovoltaic cells. However, the light scattered behind the photovoltaic cells is lost and is absorbed in the rear-side metallization.

By using a white encapsulation (e.g. EVA: Ethylene vinyl acetate) is attempted to tackle this problem. However, the use of such an encapsulation has the disadvantage that the lamination process generally used must be controlled such that no white encapsulation material surrounds the cell edge of a respective photovoltaic cell.

This is generally complex and expensive.

A so-called bifacial solar cell is described, for example in DE 10 2004 049 160 B4.

### SUMMARY

In various embodiments, a photovoltaic module is provided. The photovoltaic module may include a plurality of electrically interconnected photovoltaic cells. The photovoltaic cell may include a substrate with a front-side and a rear-side, and a metallization on the rear-side of the substrate. At least some of the plurality of electrically interconnected photovoltaic cells are at least partially bifacial photovoltaic cells. Each photovoltaic cell may include a front-side surface and a rear-side surface opposite the front-side surface where the plurality of photovoltaic cells are disposed next to each other such that there is a gap between every two adjacent photovoltaic cells on at least one side of a solar cell. The photovoltaic module may further include an encapsulation of the front-side surface and the rear-side surface of the plurality of photovoltaic cells. A first transparent cover may be arranged over the encapsulation to cover the front-side surface of the photovoltaic cells. A second transparent cover may be arranged over the encapsulation to cover the rear-side surface of the photovoltaic cells. A diffuse rear-side reflector may be arranged over the encapsulation to cover the rear-side surface of the photovoltaic cells where the diffuse rear-side reflector is disposed at a distance from the second transparent cover in the range from approximately 0.5 cm to 20 cm from the rear-side surface of the second transparent cover.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a rear-side view of a solar cell according to various embodiments;

FIG. 1B shows a cross-sectional view of the solar cell from FIG. 1A where the emitter is arranged on the front-side of the solar cell;

FIG. 1C shows a cross-sectional view of the solar cell from FIG. 1A where the emitter is arranged on the rear-side of the solar cell;

FIG. 2 shows an enlarged section of a rear-side view of a solar cell according to various embodiments;

FIG. 3 shows a cross-sectional view of one portion of a solar cell module according to various embodiments;

FIG. 4 shows a cross-sectional view of one portion of a solar cell module according to various embodiments;

FIG. 5 shows a cross-sectional view of one portion of a solar cell module arrangement according to various embodiments;

FIG. 6 shows a cross-sectional view of one portion of a solar cell module arrangement according to various embodiments; and

FIG. 7 shows a cross-sectional view of one portion of a solar cell module arrangement according to various embodiments.

### DESCRIPTION

The following detailed description refers to the accompanying drawings that show, by way of illustration, specific details and embodiments in which the invention may be practiced.

In the following detailed description, a reference is made to the accompanying drawings, which form part of this and in which specific embodiments are shown for illustration, in which the invention can be exercised. In this respect, the directional terminology such as “above”, “below/under”, “in front”, “behind”, “forward”, “rearward”, etc. are used with reference to the orientation of the described figure(s). Since components of embodiments can be positioned in a number of different orientations, the directional terminology is used only for illustration and is not limiting in any way. It should be noted that other embodiments can be used and structural or logical modifications can be undertaken without departing from the scope of protection of the present invention. It should be noted that the features of the different embodiments described herein can be combined with each other, unless not specifically stated otherwise. Therefore, the following detailed description is not to be understood in a restrictive sense, and the scope of protection of the present invention is defined by the accompanying claims.

Within the scope of this description, the terms “joined”, “connected” and “coupled” are used for describing a direct as well as an indirect joint, a direct or indirect connection and a direct or indirect coupling. In the figures, identical or similar elements are provided with identical reference numerals, where appropriate.

According to various embodiments, the electric power provided by the respective photovoltaic cell may be increased by a simple modification of the manufacturing process and the rear-side structure of a photovoltaic cell.

In various embodiments, a photovoltaic module, for example a solar cell is defined as a device, which converts the radiation energy of predominantly visible light and infra-red light (for example at least one portion of the light in the visible wavelength range of approximately 300 nm to approximately 1150 nm that additionally ultraviolet (UV)-radiation and/or infra-red (IR)-radiation up to about 1150 nm can be converted), for example of sunlight can also be directly converted into electric energy by means of the so-called photovoltaic effect.

In various embodiments, a photovoltaic module, for example a solar module is defined as an electrically connectable device with several photovoltaic cells, for example several solar cells (which are interconnected in series and/or parallel), and optionally with a weather protection (for example glass), an embedding and a frame.

According to various embodiments, the usual full-surface rear-side metallization of the photovoltaic cell (for example, in a so-called PERC-cell, PERC: Passivated Emitter Rear Cell) may be clearly opened on the border of the photovoltaic cell and as in a bifacial cell, for example so-called contact finger (which can extend with constant cross-section or with conical cross-section) generally electrically conductive current collecting structures which discharge the generated current, are pressed in the opened border area of the photovoltaic cell, so that these electrically contact the rest of the rear-side metallization. In this way, the light scattered behind the photovoltaic cell can be recaptured, namely by means of the border area/s on the rear-side of the photovoltaic cell, which have previously described current collecting structures.

Thus, according to various embodiments, a photovoltaic cell, for example a solar cell is clearly provided with bifacial characteristics on the cell border.

In conventional photovoltaic modules, it was provided to lay the white reflector (e.g. rear-side films printed on the inner side of the rear-glasses of glass-glass photovoltaic cell modules or a rear-side white encapsulation) as close as possible to the photovoltaic cell rear-side, in order to scatter less light behind the photovoltaic cell. With at least partially bifacial photovoltaic cells according to various embodiments, now it would be even more favourable to move away the rear-reflector as far from the photovoltaic cell rear-side as possible (e.g. printed on the outside of the rear-glasses in a glass-glass photovoltaic cell module), so that a maximum of light is scattered behind the solar cell. In a photovoltaic module with photovoltaic cells according to various embodiments having partially bifacial rear-side and repositioned rear-side reflector, as is explained in still more details in the following, for example, almost 100% of the light from the cell gap can be directed towards the photovoltaic cell rear-side.

In various embodiments, a photovoltaic cell is provided, including: a substrate with a front-side and a rear-side; and a metallization on the rear-side of the substrate. In a non-limiting embodiment, an area percentage of the metallization in a middle area of the substrate may be greater than in a border area which at least partially surrounds the middle area.

In a configuration, the border area may have a width in a range of approximately 0.5 cm to approximately 5 cm. In another configuration, the substrate may have a semiconductor substrate and a dielectric layer structure under the metallization on the rear-side thereof, in which contact openings are provided for electrically connecting the metallization with the semiconductor substrate. In yet another configuration, the dielectric layer structure may have at least one of the compounds Silicon nitride, Silicon oxide or Aluminum oxide. In still another configuration, the metallization in the border area can have metallic structures; e.g. contact fingers and/or at least one metal grid and/or metallic honeycombs and/or other openings in the metal surface. In a still further configuration, the metallization may have Aluminum at least in the middle area.

In a yet further configuration, the area percentage of the metallization may increase from the border area to the middle area, for example continuously or in multi-stages.

In various embodiments, a photovoltaic cell is provided, including: a substrate with a front-side and a rear-side, and an emitter area on the front-side or the rear-side of the substrate.

The rear-side of the substrate may include a middle area and a border area, which at least partially surrounds the middle area in a non-limiting embodiment. The middle area has a substantially full-surface metal layer. The border area has at least one metal-free area and a current collecting structure. The current collecting structure is electrically connected to the metal layer.

In one configuration, the border area may have a width in a range of approximately 0.5 cm to approximately 5 cm. In another configuration, the substrate may have a semiconductor substrate, an emitter (arranged on the front-side or the rear-side of the substrate), and a dielectric layer structure on the rear-side thereof, in which contact openings are provided for electrically connecting the metal layer to the semiconductor substrate. In another configuration, the dielectric layer structure may have at least one of the compounds Silicon nitride, Silicon oxide or Aluminum oxide. In another configuration, the current collecting structure in the border area can have metallic structures, e.g. contact fingers and/or at least one metal grid and/or metallic honeycombs and/or other openings in the metal surface. In another configuration, the metal layer may have Aluminium.

In various embodiments, a photovoltaic cell is provided, including: a substrate structure with a front-side and a rear-side; an emitter area on the front-side or the rear-side of the substrate structure; an optional metal layer on the rear-side of the substrate structure; an optional current collecting structure with metal-free areas on the rear-side of the substrate structure disposed next to the metal layer and electrically connected to the metal layer.

In one configuration, a metal-free border area next to the metal layer may have a width in a range of approximately 0.5 cm to approximately 5 cm. In another configuration, the substrate structure can have a semiconductor substrate, and a dielectric layer structure on the rear-side thereof, in which contact openings are provided for electrically connecting the metal layer with the semiconductor substrate. In another configuration, the dielectric layer structure can have at least one of the compounds Silicon nitride, Silicon oxide or Aluminum oxide. In another configuration, the current collecting structure in the border area can have metallic structures; e.g. contact fingers and/or at least one metal grid and/or metallic honeycombs and/or other openings in the metal layer. In another configuration, the metal layer can have Aluminum.

The bifacial solar cell(s) may be produced with another technology, e.g with a heterojunction technology (HJT) where an emitter is arranged on the back side of the substrate (or alternatively, an emitter on the front side of the substrate). A current collecting structure (electrode) may be similar to the front side current collecting structure comprising almost full area transparent metal oxides (TCOs) and metal fingers extending almost over the whole substrate width. The partially bifacial solar cells may also be of a solar cell type having both electrodes (plus-pole and minus-pole) on either the front side or the back side of the substrate. Those solar cells are also referred as interdigitated back contact solar cells (MC).

In various embodiments, a photovoltaic module is provided, including: a plurality of electrically interconnected photovoltaic cells according to various embodiments. Each photovoltaic cell has a front-side surface and a rear-side surface which is opposite the front-side surface. The plurality of photovoltaic cells are disposed next to each other such that there is a cell gap between every two respective contiguous photovoltaic cells. Each photovoltaic cell further has an encapsulation of the front-side surface and the rear-side surface of the plurality of photovoltaic cells; a first transparent cover over the encapsulation, which covers the front-side surface of the plurality of photovoltaic cells; a second transparent cover over the encapsulation, which covers the rear-side surface of the plurality of photovoltaic cells; and a diffuse rear-side reflector over the encapsulation, which covers the rear-side surface of the plurality of photovoltaic cells. The diffuse rear-side reflector is disposed such that at least a portion of the light that penetrates through at least one cell gap of the plurality of cell gaps is reflected on the rear-side surface of the plurality of photovoltaic cells.

In one configuration, the diffuse rear-side reflector may be applied on the second transparent cover or may be introduced in the second transparent cover. In another configuration, the diffuse rear-side reflector can be applied on the surface of the second transparent cover directed towards the encapsulation or can be introduced in this surface of the second transparent cover. In another configuration, the diffuse rear-side reflector can be applied on the surface of the second transparent cover directed away from the encapsulation or can be introduced in this surface of the second transparent cover. In another configuration, the diffuse rear-side reflector over the second transparent cover can be disposed opposite the encapsulation. In another configuration, the diffuse rear-side reflector can be disposed at a distance of several cm, for example in a range of approximately 1 cm to approximately 10 cm from the rear-side surface of the second transparent cover. In another configuration, the gap width can be at least of one cell gap of the several cell gaps in a range of approximately 3 mm to approximately 50 mm. In another configuration, at least a portion of the first transparent cover may have an uneven surface, for example with an edge steepness of maximum 30°, which is directed such that at least a portion of the light that penetrates through at least one cell gap of the plurality of cell gaps is reflected on the front-side surface of the plurality of photovoltaic cells; and/or it can have at least a portion of the second transparent cover, an uneven surface, for example with an edge steepness of maximum 30°, which is directed such that at least one portion of the light that penetrates through at least one cell gap of the plurality of cell gaps is reflected on the rear-side surface of the plurality of photovoltaic cells.

In various embodiments, a photovoltaic module arrangement is provided, including: at least one photovoltaic module, including: a plurality of electrically interconnected photovoltaic cells according to various embodiments. Each photovoltaic cell has a front-side surface and a rear-side surface which is opposite the front-side surface. The plurality of photovoltaic cells are disposed next to each other such that there is a cell gap between every two contiguous photovoltaic cells. Each photovoltaic cell further has an encapsulation of the front-side surface and the rear-side surface of the plurality of photovoltaic cells; a first transparent cover over the encapsulation, which covers the front-side surface of the plurality of photovoltaic cells; a second transparent cover over the encapsulation, which covers the rear-side surface of the plurality of photovoltaic cells; and a diffuse rear-side reflector under the rear-side of the at least one photovoltaic module. The diffuse rear-side reflector is disposed such that at least one portion of the light that penetrates through at least one cell gap of the plurality of cell gaps, is reflected on the rear-side surface of the plurality of photovoltaic cells.

In various embodiments, a photovoltaic module is provided, including: a plurality of electrically interconnected photovoltaic cells according to various embodiments. Each photovoltaic cell has a front-side surface and a rear-side surface which is opposite the front-side surface. The plurality of photovoltaic cells are disposed next to each other such that there is a cell gap between every two contiguous photovoltaic cells. Each photovoltaic cell further has an encapsulation of the front-side surface and the rear-side surface of the plurality of photovoltaic cells; a first transparent cover over the encapsulation, which covers the front-side surface of the plurality of photovoltaic cells; and a second transparent cover over the encapsulation, which covers the rear-side surface of the plurality of photovoltaic cells. At least one portion of the second transparent cover has an uneven surface, which is directed on the rear-side surface of the plurality of photovoltaic cells for reflecting at least one portion of the light that penetrates through at least one cell gap of the plurality of cell gaps.

In one configuration, the second transparent cover may have transparent rolled glass or a transparent film. In another configuration, the uneven surface may have a roughness of at least approximately 0.5 mm. In another configuration, the uneven surface of the second transparent cover can cover at least 30% of the cell gap area. In another configuration, the uneven surface of the second transparent cover may have several trench structures with edge steepness in a range of approximately 30° to approximately 55°. In another configuration, at least some of the plurality of photovoltaic cells can be bifacial photovoltaic cells.

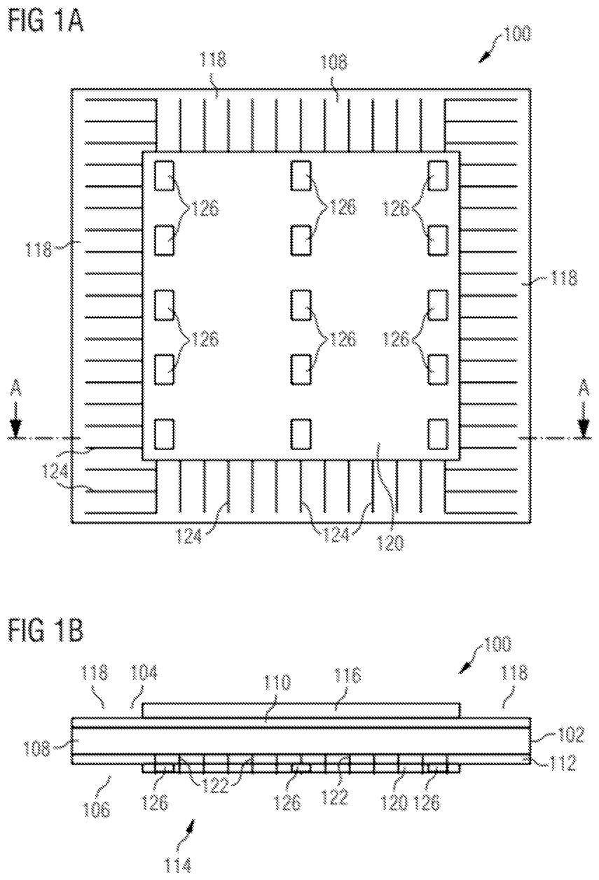

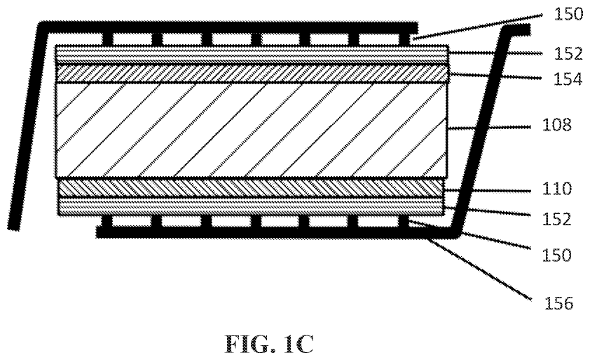

FIG. 1A shows a rear-side view of a solar cell 100 according to various embodiments and FIG. 1B shows a cross-sectional view of the solar cell 100 from FIG. 1A, along the section-line A-A represented in FIG. 1A.

The solar cell 100 is configured as a so-called PERC-solar cell (PERC: Passivated Emitter Rear Cell), that is as a solar cell, the rear-side of which is passivated.

The solar cell 100 has a substrate 102. The substrate 102 may include or essentially consist of at least one photovoltaic layer. Alternatively, at least one photovoltaic layer can be disposed on or above the substrate 102. The photovoltaic layer may include or essentially consist of semiconductor material (such as Silicon) or a composite semiconductor material (such as a composite semiconductor material III-V (such as, GaAs). In various embodiments, the Silicon may include or essentially consist of monocrystalline Silicon, polycrystalline Silicon, amorphous Silicon, and/or microcrystalline Silicon. In various embodiments, the photovoltaic layer may include or essentially consist of a semiconductor junction structure, such as a pn-junction structure, a pin-junction structure, a Schottky-type junction structure, and the like. The substrate 102 and/or the photovoltaic layer/s can be provided with a base doping of a first type of conductor.

In various embodiments, the base doping in the substrate 102 may have a dopant concentration (for example a doping of the first type of conductor, for example a p-doping, for example a doping with Boron (B) in a range of approximately 10¹³ cm⁻³ to 10¹⁸ cm⁻³ , for example in a range of approximately 10¹⁴ cm⁻³ to 10¹⁷ cm⁻³, for example in a range of approximately 10¹⁵ cm⁻³ to 2*10¹⁶ cm⁻³.

The substrate 102 may be made from a solar cell wafer and may have, for example round shape such as circular or polygonal shape, such as square shape. In various embodiments, the solar cells of the solar module however may also have a non-quadratic shape. In these cases, the solar cells of the solar module may be formed, for example by separating (for example cutting) and thereby parting one or more (also referred to in their shape as standard solar cell) solar cell(s) into several non-quadratic or square solar cells. In various embodiments, it can be provided in these cases to undertake the adaptations of the contact structures in the standard solar cell, for example rear-side cross-structures can additionally be provided.

In various embodiments, the solar cell 100 can have the following dimensions: the width in a range of approximately 5 cm to approximately 50 cm, the length in a range of approximately 5 cm to approximately 50 cm, and the thickness in a range of approximately 50 μm to approximately 300 μm.

The solar cell 100 may have a front-side (also referred to as light incident side) 104 and a rear-side 106.

According to various embodiments, a base area 108 and an emitter area 110, which is illustrated in FIG. 1B as being on the front side of the base area 108 but may alternatively be present on the rear side of the base area 108 as depicted in FIG. 1C, are formed in the photovoltaic layer. The base area 108 is doped, for example with dopant of a first type of doping (also referred to as first type of conductor), for example with dopant of p-type of conductor, for example with dopant of the III^{rd} main group of the periodic system, for example with Boron (B). The emitter area 110 is doped, for example with dopant of a second type of dopant (also referred to as second type of conductor), wherein the second doping type is opposite the first doping type, for example with dopant of the n-type of doping, for example with dopant of the V^{th} main group of the periodic system, for example with Phosphorous (P).

In various embodiments, a selective emitter can optionally be formed in the emitter area 110. Furthermore, electrically conductive current collecting structures (for example a metallization such as a Silver metallization, which can be formed by burning a Silver paste (the Silver paste can be formed of Silver particles, Glass frit particles and organic excipients)) such as so-called contact fingers and/or so-called Busbars (not represented) can be provided on the front-side 104 of the solar cell 100.

In various embodiments, an anti-reflection layer (for example including or consisting of Silicon nitride) can optionally be applied on the exposed surface of the emitter area 110 (not represented).

Furthermore, a plurality of metallic solder pads (not represented) can be provided. Each solder pad is electrically connected to the emitter area, for example by means of a current collecting structure.

In various embodiments, the areas with increased dopant concentration can be doped with a suitable dopant such as Phosphorous. In various embodiments, the second type of conductor can be a p-type of conductor and the first type of conductor can be an n-type of conductor. Alternatively, the second type of conductor can be an n-type of conductor and the first type of conductor can be a p-type of conductor in various embodiments.

For reasons of the simpler explanation, the individual elements which are provided on the front-side 104 of the solar cell 100, are not represented in the figures.

Furthermore, the solar cell 100 has a dielectric layer structure (also referred to as Passivation layer) 112 on the rear-side 106 thereof. The dielectric layer structure 112 has, for example a double layer of thermal oxide and Silicon nitride. However, alternative layer structures are necessarily also possible for the dielectric layer structure 112.

For example, a random layer-stack with layers having one or more of the compounds Silicon nitride, Silicon oxide or Aluminum oxide can be provided in the dielectric layer structure 112.

A metallization 114 is provided on the side of the dielectric layer structure 112 opposite the substrate 102. The area percentage of the metallization 114 (for example of Aluminum and/or Silver) in a middle area 116 of the substrate 102 is greater than in a border area 118 of the substrate 102, which at least partially (that is partially or completely) surrounds the middle area 116. Thus, in various embodiments, the metallization 114 has essentially two partial areas, namely:
an essentially full-surface first partial area 120, which is disposed on the dielectric layer structure 112 substantially in the middle area 116 of the substrate 102 and electrically connected to the substrate 102, for example to the base area 108 of the substrate 102 by means of the contact holes (also referred to as contact openings, for example local contact openings (LCO) 122, which extend through the dielectric layer structure 112, (in this connection it should be noted that in various embodiments, a metallization paste can also be used which is configured to penetrate the Nitride layer (so-called fire-through metallization paste). Thereby, a contact through the dielectric layer structure can be made even without laser opening); and
a second partial area 124, which is disposed on the dielectric layer structure 112 substantially in the border area 118 of the substrate 102 ;
the second partial area 124 is formed, for example of current collecting structures which are similar to the current collecting structures on the front-side 104 of the substrate 102;
for example electrically conductive contact fingers (for example made of the same material, for example made of the same metal as the first partial area 120, for example made of Aluminum, or another material, for example another metal) can be provided in the second partial area 124;
the shape of the current collecting structures is generally random;
the current collecting structures are at least partially electrically connected to the first partial area and/or (likewise for example by means of contact holes to the substrate 102, for example to the base area 108 of the substrate 102.

The area percentage of the metallization 114 in the middle area 116 of the substrate 102 is greater than in the border area 118 of the substrate 102, which at least partially surrounds the middle area 116. Even if the border area 118 in FIG. 1A completely surrounds the middle area 116, alternatively it can be provided that the border area 118 only partially surrounds the middle area 116. The shape and connection of the individual elements of the current collecting structures can be random, for example can be provided with contact fingers and/or at least a metal grid and/or metallic honeycombs and/or other openings in the metal surface (with random surface cross-section) as described above.

Clearly, the border area 118 is substantially free from metal (except for the metal of the second partial area 124 of the metallization 114), so that the exposed area of the dielectric layer structure 112 is translucent and thereby for example, the light penetrating through a cell gap, for example, which is reflected on the rear-side in any way (for example, diffuse) in the direction towards the rear-side 104 of the substrate 102, can reach back in the base area 108 of the substrate 102 and can form excitons there, whereby an additional contribution is made for generating electric energy.

Therefore, the efficiency of the solar cell 100 is significantly increased as against a purely front-side solar cell. Illustratively, the solar cell 100 thus represents a part-bifacial (in other words partially bifacial) solar cell 100. The part-bifacial solar cell 100 may also have the effect of an additionally reduced series resistance as against the 100% bifacial solar cell.

The border area 118 can have the width in a range of approximately 0.5 cm to approximately 5 cm, for example a width in the range of approximately 1 cm to approximately 3 cm.

The middle area 116, which is substantially covered on full-surface with a metal, for example Aluminum, has an area in the range of approximately 213 cm² to approximately 31 cm², for example in the range of approximately 185 cm² to approximately 92 cm².

Furthermore, a plurality of metallic solder pads 126 can be provided. Each metallic solder pad 126 is electrically connected to the metallization 114.

In various embodiments, the area percentage of the metallization 114 increases from the border area 118 to the middle area 116, for example continuously or in steps.

As depicted in FIG. 1C, a bifacial solar cell is represented having a heterojunction technology (HJT) where an emitter 110 is arranged on the back side of the base body 108, e.g. substrate or alternatively, an emitter is arranged on the front side of the substrate (not shown). A current collecting structure (electrode) may include a transparent metal oxide layer 152 (e.g. TCOs, such as indium tin oxide in a non-limiting embodiment) and metal fingers 150 extending almost over the whole width of the base body 108. A front surface field 154 (e.g. i+n−aSi) may be arranged between the base body 108 and the transparent metal oxide layer 152. Interconnectors 156 may connect solar cells within the module, such as SmartWire Connection Technology™ interconnectors from Meyer Burger™. The partially bifacial solar cells may also be of a solar cell type having both electrodes (plus-pole and minus-pole) on either the front side or the back side of the substrate. This type of solar cells is referred to as an interdigitated back contact solar cell (IBC).

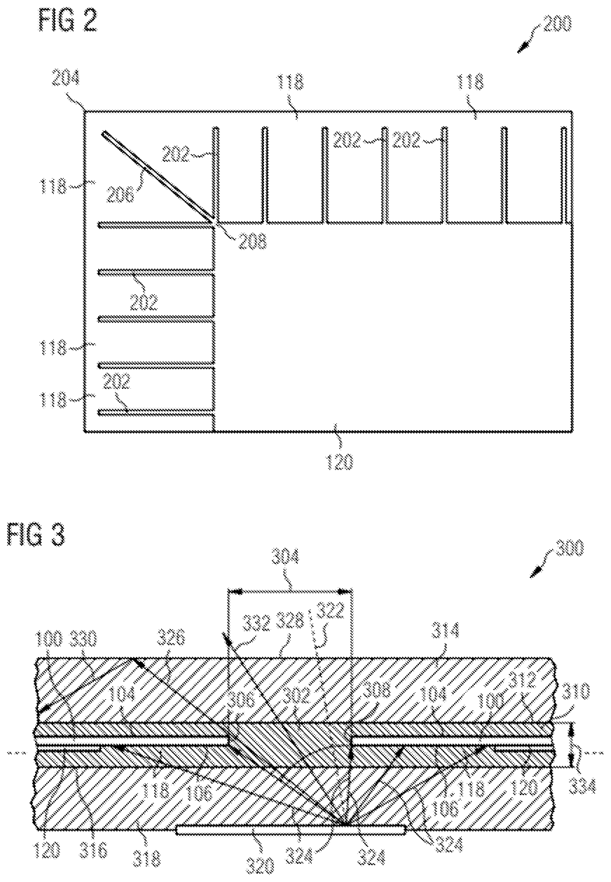

FIG. 2 shows an enlarged section 200 of a rear-side view of a corner of a solar cell according to various embodiments. The solar cell may have a similar or identical construction as the solar cell 100 represented in FIG. 1A and FIG. 1B, however. In the solar cell represented in FIG. 2, the rear-side current collecting structure 202 has a different shape in the border area 118 (i.e. the second part-area of the metallization) than the current collecting structure 124 in the border area 118 in FIG. 1B. So, the rear-side current collecting structure 202 in FIG. 2 is formed exclusively from straight line shaped contact fingers 202, which are electrically connected to the metal layer 120 in the middle area 116 of the solar cell 200 on full-surface, wherein the contact fingers 202 extend substantially perpendicular to a respective edge of the solar cell, however, do not extend up to respective edge. In the corner 204 itself, a respective contact finger 206 is provided as part of the current collecting structure, which extends in straight line from the corresponding corner 208 of the first part-area 120 to the corner 204 of the solar cell 200, however does not contact this. In the current collecting structures 124 according to FIG. 1B, angled contact fingers 124 with several part-areas are provided, which can be disposed at an angle with respect to each other.

Clearly, the border area 118 of the solar cell 100 thus represents a bifacial border area, which is configured for capturing light, which can reach into the base area 108 of the solar cell 100 to be used there for power generation.

Even though the solar cell 100 is a PERC-solar cell, the embodiments are however not limited to such a PERC-solar cell. The described part-bifacial solar cell can be of any type of solar cell, only with respective correspondingly matched rear-side metallization.

If for example, the rear-side of the substrate of a solar cell is not completely passivated as in a PERC solar cell, then additionally in the border area in which the rear-side of the base area is partially exposed, this can be additionally covered with a passivation layer and the second part-area of the current collecting structure can then be disposed on the passivation layer. The passivation layer can have or be Silicon nitride. The passivation layer can have one or more dielectric layers.

FIG. 3 shows a cross-sectional view of a part of a solar cell module 300 according to various embodiments.

As will be explained in more details in the following, in the conventional glass-glass-modules, the light radiation is reduced behind the solar cells, in which a reflection structure, for example in the form of a reflection layer, for example in the form of a partial or even full-surface white ceramic printing 320 is laid on the module inner side in contrast to the representation in FIG. 3. In conventional glass-glass-modules with solar cells according to various embodiments, for example more than 33% of the light (about 6 W/module) through the incident light can be reclaimed.

In this connection, the above described solar cell according to various embodiments is distinctive, because the border area is excellent for capturing the light reflected on the rear-side (for example, diffuse) from the reflection structure and additionally the electric resistance of the rear-side of the solar cells is low, whereby the power of the solar cell module according to various embodiments is increased.

The solar cell module 300 as an example of a photovoltaic module according to various embodiments has, for example, several electrically interconnected (in series and/or parallel) solar cells, as these have been described above or are explained in more details in the following. Each solar cell 100 has a front-side surface 104 and a rear-side surface 106 which is opposite the front-side surface 104. The solar cells 100 are disposed next to each other at a distance from each other. Thus, there may be a solar cell gap (in the following also referred to as cell gap) 302 between every two directly contiguous solar cells 100. In a non-limiting embodiment, there may be no solar cell gap between every two contiguous solar cells 100.

A gap width 304 (measured between two edges 306, 308 facing each other, of two adjacent solar cells 100) at least of a cell gap 302 of the several cell gaps 302 is, for example in the range of approximately 3 mm to approximately 50 mm, for example in the range of approximately 5 mm to approximately 30 mm, for example in the range of approximately 10 mm to approximately 25 mm.

The plurality or variety of solar cells 100 are, for example substantially encapsulated (obviously these are still not electrically contacted) for protection from moisture or even mechanical damages. An encapsulation 310 is provided therefor, which substantially completely surrounds the solar cells 100 and thus encapsulates the front-side surface and the rear-side surface of the plurality of photovoltaic cells. An example for an encapsulation material which can be used for the encapsulation 310 is transparent or translucent EVA (EVA: Ethylene vinyl acetate) for visible light. The encapsulation 310 can have a thickness 334 in the range of approximately 0.2 mm to approximately 3 mm, for example in the range of approximately 0.4 mm to approximately 2.0 mm, for example in the range of approximately 0.6 mm to approximately 1.5 mm, for example approximately 0.9 mm.

A front glass 314, for example a float glass or even a translucent film can be fixed, for example glued on the upper side 312 of the encapsulation 310. The front glass 314 represents an example of the first (optical, for example for visible light) transparent cover 314 over the encapsulation 310, which covers the front-side surface 104 of the plurality of solar cells 100.

A rear-side glass 318, for example similarly a float glass (for example with a thickness in the range of approximately 2 mm to approximately 15 mm, for example in the range of approximately 4 mm to approximately 6 mm) is fixed, for example glued on the rear-side 316 of the encapsulation 310. The rear-side glass 318 represents an example of the second (optical, for example for visible light) transparent cover 318 over the encapsulation 310, which covers the rear-side surface 106 of the plurality of solar cells 100.

A diffuse rear-side reflector 320 is provided on the side of the rear-side glass 318 turned away from the encapsulation 310. The diffuse rear-side reflector 320 can be made, for example of a ceramic layer, for example a white ceramic layer which can be printed, for example on the rear-side glass 318 facing away from the side of the rear-side glass 318. However, the diffuse rear-side reflector 320 alternatively can also be disposed within the rear-side glass 318. Further, the diffuse rear-side reflector 320 can be applied on the surface of the second transparent cover 318 directed towards the encapsulation 310 or can be introduced in this surface 316 of the second transparent cover 318.

The diffuse rear-side reflector 320 can further be formed of a ceramic grid, generally for example made of a low-melting glass (with a melting point of less than 650° C.), which for example has Titanium oxide fractions. The diffuse rear-side reflector 320 can be printed, for example by using an organic binder. Furthermore, one or more organic thermoset inks (for example, with ceramic pigments) can be provided as diffuser rear-side reflector 320. A structured rear-side boundary layer with metal coating as diffuser rear-side reflector 320 can also be used in various embodiments.

The diffuse rear-side reflector 320 can extend completely over the entire area of the rear-side glass 318 or also only over a portion of the same. The diffuse rear-side reflector 320 should however cover the cell gap/s 302 at least substantially completely laterally, can optionally extend still farther laterally over the areas of the cell gaps 302, for example on approximately at least 10% of the width of the respective cell gap 302, for example on approximately at least 20% of the width of the respective cell gap 302, for example on approximately at least 30% of the width of the respective cell gap 302. In a matrix shaped arrangement of the solar cells 100 within the solar cell module 300, thus for example, there is a substantially grid-like structure of the diffuse rear-side reflector 320 extending along the cell gap 302. The diffuse rear-side reflector 320 is dimensioned and disposed within the solar cell module 300 such that at least a portion of the light that penetrates through the cell gap/s 302 (symbolized in FIG. 3 by means of a first arrow 322) is reflected (for example, diffuse) on the rear-side surface of the plurality of solar cells 100 and therefore, primarily on the rear-side light collecting bifacial border areas 118 of the solar cells 100 (this is symbolized in FIG. 3 by means of second arrows 324). The light 322 penetrating through the cell gap 302 is thus clearly reflected diffuse on the rear-side of the solar cells 100 by the diffuse rear-side reflector 320 and the cell gap 302 between the solar cells 100. A large portion of the reflected (for example, diffuse) light reaches the border areas 118 of the solar cells 100, enters into the substrate 102 there, for example the base area 108, and produces additional excitons there, whereby the efficiency of the solar cells 100 is increased further. Another portion (symbolized in FIG. 3 by means of a third arrow 326) of the diffuse reflected light again penetrates through the cell gaps 302 and but can be totally reflected on the front side surface 328 of the first cover 314 (symbolized in FIG. 3 by means of a fourth arrow 330). Only a relatively smaller portion of the diffuse reflected light again penetrates through the cell gaps 302 and then leaves the solar cell module 300 through the front glass 314 (symbolized in FIG. 3 by means of a fifth arrow 332).

Therefore, the original disadvantage of the power loss by scattering of light behind the solar cell 100 can purposely be used by application of a (at least partially) bifacial solar cell 100 according to various embodiments in a glass-glass module, for example the solar cell module 300. In order to enhance the light scattering behind the bifacial solar cell 100, the white (ceramic) printing can be laid on the module outer side in a glass-glass module, for example the solar cell module 300, whereby lesser light again exits from the solar cell module 300 than that occurs conventionally.

The lower the cell gap 302 between the solar cells 100 (i.e. for example, thicker the rear-side glass 318 is), the more light can be captured by the solar cell module 300, since the opening angle of the light scattering cone that can still escape from the solar cell module 300 becomes increasingly smaller.

In various embodiments, a solar cell module with a transparent film cover 300 (e.g. consisting of ETFE: Ethylene Tetrafluoroethylene or ECTFE: Ethylene Chlorotrifluoroethylene) with an external white 4 mm glass and the above described partially bifacial solar cells 100 is used—about 80% light capture is thus possible in the cell gap. Such a solar cell module 300 can provide, for example approximately 10 additional W/module in comparison to a conventional solar cell module.

In various embodiments, the diffuse rear-side reflector 320 can be disposed at a distance of several cm, for example in the range of approximately 1 cm to approximately 10 cm from the surface of the second transparent cover 318 in physical contact with the encapsulation 310.

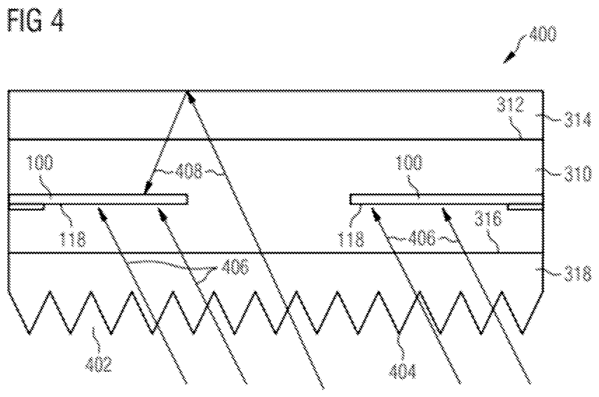

FIG. 4 shows a cross-sectional view of one portion of a solar cell module 400 according to various embodiments. The solar cell module 400 according to FIG. 4 is very similar to the solar cell module 300 according to FIG. 3, which is why only the differences are explained in more details in the following.

The solar cell module 400 according to FIG. 4 differs from the solar cell module 300 according to FIG. 3 essentially by a different configuration of the diffuse rear-side reflector 402.

Thus, in the solar cell module 400 according to FIG. 4, the diffuse rear-side reflector 402 is not formed of a white ceramic printing, but by a targeted structuring of the rear-side surface of the second transparent cover 318, whereby this surface is formed uneven. Even the rear-side structuring can be provided completely over the entire rear-side surface of the second transparent cover 318, or can extend over only one portion of the same. Similar to the above described embodiment, for this case, it can be provided that essentially the areas of the cell gaps 302 can be laterally overlaid by the structured areas 404, optionally still farther laterally over the areas of the cell gaps 302, for example on approximately at least 10% of the width of the respective cell gap 302, for example on approximately at least 20% of the width of the respective cell gap 302, for example on approximately at least 30% of the width of the respective cell gap 302. Thus, at least a portion of the second transparent cover 318 has an uneven surface, for example with the edge steepness of about 30° to maximum 45°, which is configured such that at least one portion of the light that penetrates through at least one cell gap 302 of the plurality of cell gaps 302 is reflected on the rear-side surface 106 of the plurality of solar cells 100 (for example diffuse), and therefore, essentially on the rear-side border areas 118 of the solar cells 100 (this is symbolized in FIG. 4 by means of sixth arrow 406).

In addition, it can be provided that at least one portion of the first transparent cover 314 also has an uneven surface, for example with the edge steepness of maximum 30° (not represented), which is configured such that at least one portion of the light that penetrates through at least one cell gap 302 of the plurality of cell gaps 302 is reflected (for example diffuse) on the front-side surface of the plurality of solar cells 100 (this is symbolized in FIG. 4 by means of a seventh arrow 408).

Clearly, the structuring of the rear-side surface of the second cover 318 is configured such that at least one portion of the light penetrating through the cell gaps 302 is totally reflected by the structuring 404 and thereby deflected towards the rear-side border area 118 of the respective solar cell 100. In other words, under oblique light conditions, the light is coupled by the front-side structure (i.e. by the first cover 314) fairly flat in the solar cell module 400 below an angle of total reflection and is deflected on the rear-glass (i.e. for example on the structured rear-side surface of the rear-side glass 318). The effect produces corresponding caustics on the edge of the solar cell rear-side. With the partially bifacial solar cells 100 according to various embodiments, this light can be absorbed over the exposed rear-side of the substrate 102 and can be used for additional power generation.

In various embodiments, the second transparent cover 318 is formed of glass, for example rolled glass, alternatively formed of one or more transparent structured or corrugated films, for example one or more ETFE films (wherein the individual films can be laminated together).

The second transparent cover 318 of glass provided with the structuring can also be referred to as a deeply structured glass. A deeply structured glass has (similar to the alkaline pyramid texture of a solar cell) a highly reduced rear-reflection and an improved light coupling.

The structuring can have, for example a structuring depth in the range of approximately 0.5 mm to approximately 5 mm, for example in the range of approximately 0.5 mm to approximately 3 mm, for example in the range of approximately 0.5 mm to approximately 1.5 mm.

The structuring can be done, for example by rolling of the rear-side surface of the second cover 318. The structuring can however be formed in any other suitable manner. In this connection, it should be noted that the rear-side surface of the second cover 318 must not be coated reflecting additionally in various embodiments.

In various embodiments, the rear-side reflection of the light penetrating through the cell gaps 302 can be realized by that a corresponding reflection structure is mounted in a solar cell module frame.

Thus, it is possible according to various embodiments to realize the diffuse rear-side reflector within the solar cell module, for example by means of a reflecting layer (for example by means of a ceramic white printing) or by means of a structuring of the rear-side cover of the type such that a total reflection of at least one portion of the light penetrating through the cell gaps occurs. Further, it is provided in various embodiments, to provide the diffuse rear-side reflector outside the solar cell module, but within a solar cell module arrangement, for example by means of a diffuse reflecting plate which is mounted in a mounting frame of the solar cell module arrangement, as it is explained in more details in the following.

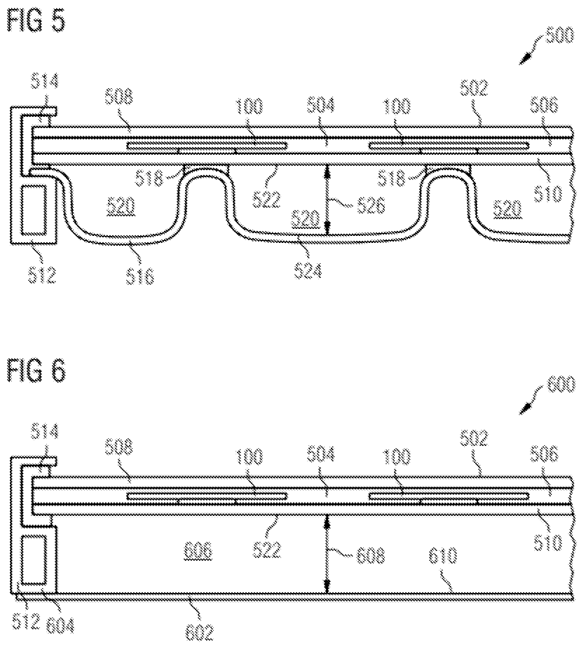

Clearly, in the embodiments represented in FIG. 5 and FIG. 6, partially or completely bifacial solar cells 100 (as represented in FIG. 1 and FIG. 2) or completely bifacial solar cells are used and a diffuse rear-side reflector (for example, a white rear-side reflector or a diffuse scattering metal sheet) is mounted in a transparent encapsulation, for example, 2 cm to 3 cm behind this (e.g. corresponding to the respectively provided solar cell module frame thickness). This can be done, for example in a roof-integration but also in the open area. In the cell gap between the solar cells 100, the scattered light is backscattered on the diffuse rear-side reflector, for example on the white rear-side reflector and supplied to the partially bifacial solar cells' rear-side. Based on the high aspect ratio due to lower cell gap width and at the standard cell gap widths (about 3 mm) at up to 10 times the retracted scattered body (i.e. diffuse rear-side reflector), the solid angle at which the light can escape beamed from behind the hollow space can be very low and is almost completely captured.

In an installation of the solar cell module arrangement 500, 600, 700, for example on an inclined roof, the diffuse rear-side reflector 320 can be formed, for example from one or more white film(s) or one or more plates on roof tiles or by in-roof elements with a white surface.

In an installation of the solar cell module arrangement 500, 600, 700, for example one or more white film(s) or one or more reflecting plate(s) can be provided on a flat-roof for realizing the diffuse rear-side reflector 320.

FIG. 5 shows a cross-sectional view of one portion of a solar cell module arrangement 500 according to various embodiments.

As an example of a photovoltaic module arrangement, the solar cell module arrangement 500 has one or more solar cells 100. A section of a border section of one such solar cell module 500 is represented in FIG. 5.

The solar cell module 500 has a plurality of electrically interconnected (in series and/or parallel) solar cells 100 according to various embodiments, as these have been described above, for example in connection with FIG. 1 and FIG. 2. Each solar cell 100 has a front-side surface 104 and a rear-side surface 106 which is opposite the front-side surface 104. The solar cells 100 are disposed adjacent to each other such that there may be a cell gap 504 between every two contiguous solar cells 100. Furthermore, the solar cell module 500 has an encapsulation 506 (for example made of EVA) of the front-side surface and the rear-side surface of the solar cells 100, which substantially completely surrounds the solar cells 100 (however still enables an electrical contacting of the solar cells 100 through the encapsulation 506). A first transparent cover 508 is provided over the encapsulation 506; for example, which is glued on the encapsulation 506, and which covers the front-side surface of the solar cells 100. A second transparent cover 510 is provided over the encapsulation 506 on the side of the encapsulation 506 opposite the first transparent cover 508, for example similarly glued on this. The second transparent cover 510 covers the rear-side surface 106 of the solar cells 100.

Furthermore, the solar cell module arrangement has a mounting frame 512 which surround and thereby hold the solar cell module 500 on the border thereof by means of one or more clamps (which can be provided with a cushioning material, for example soft rubber or a bond to prevent damage to the solar cell module 500) 514. In addition, a reflecting plate 516 (for example a metal sheet or a plate coated with a metal layer) used as diffuse rear-side reflector 516 can be held in the mounting frame 512. The reflecting plate 516, generally the diffuse rear-side reflector 516 is disposed outside the solar cell laminate 502 according to these embodiments. In various embodiments, the reflecting plate 516 can be curved or corrugated, so that for example the reflecting plate 516 can be additionally fastened for edge holding by means of the mounting frame 512 under the solar cells 100 on the solar cell module 500 for improving stability of the solar cell module arrangement 500 (for example by means of a holding structure 518 (for example by means of an adhesive 518). In this way, the hollow spaces 520 are clearly formed, the height 526 (i.e. distance of the underside 522 of the solar cell module 500 up to the upper side 524 of the reflecting plate 516) thereof is in the range of approximately 0.5 cm to 20 cm, for example in the range of approximately 1 cm to 10 cm, for example approximately 3 cm.

Thus, the reflecting plate 516, generally the diffuse rear-side reflector 516 can be disposed outside the laminate of the solar cell module 500. The metal can be a matt metal or a reflective metal provided with an embossing (for example, which can be small dents of the order of few mm diameter). Furthermore, instead of metal, a plate can also be coated with a white ceramic printing or a white plastic structure. Generally in this connection, any diffuse reflecting material can be used for the reflecting plate 516 or as (at least partially (at least laterally under the cell gaps 504)) coating of the reflecting plate 516.

Generally, a diffuse rear-side reflector 516 under the rear-side of the solar cell module 500 can be provided in various embodiments, wherein the diffuse rear-side reflector 516 is disposed such that at least one portion of the light that penetrates through at least one cell gap 504 of the plurality of cell gaps 504 is reflected (for example, diffuse) on the rear-side surface of the solar cells 100. In various embodiments, only a single hollow space is formed, however with grid points behind each of the solar cells 100.

FIG. 6 shows a cross-section of one portion of a solar cell module arrangement 600 according to various embodiments.

The solar cell module arrangement 600 according to FIG. 6 is very similar to the solar cell module arrangement 500 according to FIG. 5, which is why only the differences are explained in more details in the following.

The solar cell module arrangement 600 differs from the solar cell module arrangement 500 according to FIG. 5 substantially by a different configuration, holding and positioning of the diffuse rear-side reflector.

According to these embodiments as well, a reflecting plate 602 (for example a metal sheet or a plate coated with a metal layer or a white film) used as diffuse rear-side reflector 602 is provided, which is held on the mounting frame 512, however not in the clamp 514, but for example at the lower end 604 of the mounting frame 512. The reflecting plate 602, generally the diffuse rear-side reflector 602 is likewise disposed outside the solar cell laminate 502 according to these embodiments. In various embodiments, the reflecting plate 602 can be curved or corrugated or even substantially flat. In various embodiments, thus only one single hollow space 606 is formed between the solar cell module 500 and the reflecting plate 602. The hollow space 606 has, for example a height 608 (i.e. a distance from the underside 522 of the solar cell module 500 up to the upper side 610 of the reflecting plate 602) in the range of approximately 0.5 cm to 20 cm, for example in the range of approximately 1 cm to 10 cm, for example approximately 3 cm.

Thus, the reflecting plate 602, generally the diffuse rear-side reflector 602, can be disposed outside the laminate of the solar cell laminate 502. The metal can be a matt metal. Furthermore, instead of metal, a plate can also be coated with a white ceramic printing or a plastic film. Generally, any diffuse reflecting material can be used in this connection for the reflecting plate 602 or as (at least partial (at least laterally under the cell gaps 504)) coating of the reflecting plate 602.

In various embodiments, generally here as well, a diffuse rear-side reflector 602 is provided under the rear-side of the solar cell module 500. The diffuse rear-side reflector 602 is disposed such that at least one portion of the light that penetrates through at least one cell gap 504 of the plurality of cell gaps 504 is reflected (for example diffuse) on the rear-side surface of the solar cells 100.

By using a partially bifacial solar cell in a solar cell module with two transparent covers, for example a glass-glass solar cell module, the original disadvantage of the power loss can be purposely used advantageously by scattering of light behind the solar cell. To amplify the light scattering behind the bifacial solar cell, the hollow space behind the solar cells, for example in roof-integration can be coloured white and the solar cell module can be or is configured transparent. By a structured rear-side, the light capture can additionally be amplified further (thus a combination of the embodiments of FIG. 5 or FIG. 6 with the embodiment of FIG. 4 is also possible), since the light is deflected still farther behind the solar cell. The deeper the cell gap between the solar cell, the more light can be captured by the solar cell module, since the aperture angle of the scattering cone of light which can still escape, has been diminishing. Ideally, almost 100% of light between the solar cells can be used.

For example, in the embodiments in which the diffuse rear-side reflector is attached outside the solar cell laminate, the cell interval and the distance to the border of the solar cell module can be greater than in a conventional solar cell module. Thus, for example the cell-interval can be in the range of approximately 3 mm to approximately 50 mm or even above that, for example in the range of approximately 10 mm to approximately 50 mm.

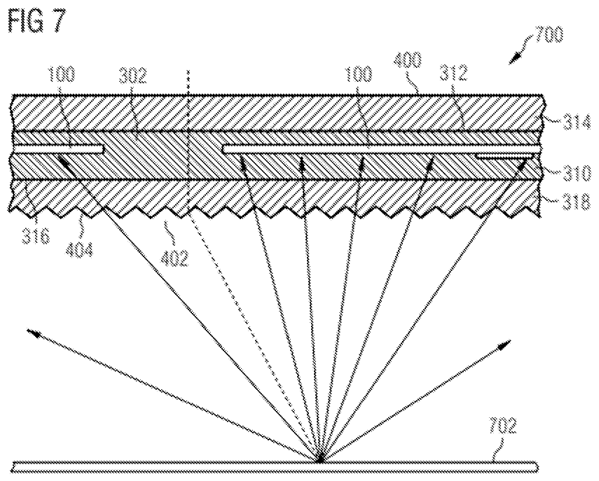

FIG. 7 shows a cross-sectional view of one portion of a solar cell module arrangement 700 according to various embodiments.

In the solar cell module arrangement 700, a solar cell module 400 according to FIG. 4 is clearly provided and a reflecting film or plate 702 provided outside the solar cell module 400 at a distance therefrom, which is disposed such that at least one portion of the light that penetrates through at least one cell gap 302 of the plurality of cell gaps 302, is reflected (for example, diffuse) on the rear-side surface of the solar cells 100.

Thus, clearly two diffuse rear-side reflectors are provided in this embodiment, namely a diffuser rear-side reflector within the solar cell module 400 on the one side and a diffuser rear-side reflector outside the solar cell module 400 on the other side.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A photovoltaic module, comprising:
a plurality of electrically interconnected photovoltaic cells,
each photovoltaic cell comprising:
a substrate with a front-side and a rear-side; and
a metallization on the rear-side of the substrate;
wherein at least some of the plurality of electrically interconnected photovoltaic cells are at least partially bifacial photovoltaic cells;
wherein each photovoltaic cell includes a front-side surface and a rear-side surface which is opposite the front-side surface, wherein the plurality of photovoltaic cells are disposed next to each other such that there is a gap between every two adjacent photovoltaic cells on at least one side of a solar cell;
an encapsulation of the front-side surface and the rear-side surface of the plurality of photovoltaic cells;
a first transparent cover over the encapsulation, which covers the front-side surface of the plurality of photovoltaic cells;
a second transparent cover over the encapsulation, which covers the rear-side surface of the plurality of photovoltaic cells;
a diffuse rear-side reflector over the encapsulation, which covers the rear-side surface of the plurality of photovoltaic cells; wherein at least one or more portions of the diffuse rear-side reflector is disposed at a distance from the second transparent cover in the range from approximately 0.5 cm to approximately 20 cm from the rear-side surface of the second transparent cover.

2. The photovoltaic module of claim 1,
wherein the diffuse rear-side reflector is disposed such that at least one portion of the light penetrating through at least one cell gap of the plurality of cell gaps is reflected on the rear-side surface of the plurality of photovoltaic cells.

3. The photovoltaic module of claim 2,
wherein the gap width of at least one cell gap of the several cell gaps ranges from approximately 3 mm to approximately 50 mm.

4. The photovoltaic module of claim 3,
wherein at least one portion of the first transparent cover comprises an uneven surface configured such that at least one portion of the light penetrating through the at least one cell gap of the plurality of cell gaps is reflected on the front-side surface of the plurality of photovoltaic cells; or
wherein at least one portion of the second transparent cover comprises an uneven surface configured such that at least one portion of the light that penetrates through the at least one cell gap of the plurality of cell gaps is reflected on the rear-side surface of the plurality of photovoltaic cells.

5. The photovoltaic module of claim 1, wherein the diffuse rear-side reflector is curved or corrugated.

6. The photovoltaic module of claim 5, further comprising a mounting frame configured to hold the diffuse rear-rear side reflector.

7. The photovoltaic module of claim 5, further comprising a holding structure arranged on a rear side of the second transparent cover, wherein the holding structure is configured to stabilize at least one or more portions of the diffuse rear-side reflector closest to the second transparent cover.

8. The photovoltaic module of claim 1, wherein the diffuse rear-side reflector is substantially flat.

9. The photovoltaic module of claim 1,
wherein the second transparent cover comprises transparent rolled glass or a transparent film.

10. The photovoltaic module of claim 4,
wherein the uneven surface comprises a roughness of at least approximately 0.5 mm.

11. The photovoltaic module of claim 4,
wherein the uneven surface of the second transparent cover covers at least 30% of the cell gap area.

12. The photovoltaic module of claim 4,
wherein the uneven surface of the second transparent cover comprises several trench structures with edge steepness in the range of approximately 30° to approximately 55°.

13. The photovoltaic module of claim 1,
wherein the area percentage of the metallization in a middle area of the substrate is greater in a border area, which at least partially surrounds the middle area.
